(19) United States
(12) Patent Application Publication
(10) Pub. No.: US 2018/0090221 A1
(43) Pub. Date: Mar. 29, 2018

(54) BOOT-UP CONTROL CIRCUIT AND SEMICONDUCTOR APPARATUS INCLUDING THE SAME

(71) Applicant: SK hynix Inc., Icheon-si Gyeonggi-do (KR)

(72) Inventors: Yong Sun KIM, Icheon-si Gyeonggi-do (KR); Tae Kyun SHIN, Icheon-si Gyeonggi-do (KR)

(73) Assignee: SK hynix Inc., Icheon-si Gyeonggi-do (KR)

(21) Appl. No.: 15/434,990

(22) Filed: Feb. 16, 2017

(30) Foreign Application Priority Data
Sep. 26, 2016 (KR) 1020160123126

(51) Int. Cl. G11C 17/18; G11C 17/16; G11C 29/12

(52) U.S. Cl. CPC G11C 17/18; G11C 29/12; G11C 17/16

(57) ABSTRACT

A boot-up control circuit may be provided. The boot-up control circuit may include a fuse array including a one or more normal fuses and one or more dummy fuses. The boot-up control circuit may include a fuse array controller configured to determine whether or not to start a normal boot-up operation for the one or more normal fuses according to a comparison result between expected data and test fuse data output from the one or more dummy fuses through a test boot-up operation.

### CROSS-REFERENCES TO RELATED APPLICATION

The present application claims priority under 35 U.S.C. § 119(a) to Korean application number 10-2016-0123126, filed on Sep. 26, 2016, in the Korean Intellectual Property Office, which is incorporated herein by reference in its entirety.

### BACKGROUND

### 1. Technical Field

Various embodiments may generally relate to a semiconductor circuit, and more particularly, to a boot-up control circuit and a semiconductor apparatus including the same

### 2. Related Art

A memory cell in which a defect occurs (hereinafter, referred to as defective cell) in the semiconductor apparatus may be detected through a test.

When an address provided from the outside is an address for accessing the defective cell in an operation of the semiconductor apparatus, a redundant memory cell (hereinafter, referred to as redundant cell) which is assigned to the defective cell may be accessed other than the defective cell and this operation may refer to as a repair operation.

Address information for accessing the defective cell may refer to defective address information.

In recent years, an E-fuse capable of recoding information through a rupture, even after packaging, may be used.

The semiconductor apparatus may include a fuse array in which the defective address information is programmed (for example, stored through a rupture operation) by accessing a plurality of e-fuses through a method similar to a memory cell accessing method and then the pre-stored defective address information is read to be used in the following boot-up operation.

### SUMMARY

In an embodiment of the present disclosure, a boot-up control circuit may be provided. The boot-up control circuit may include a fuse array including at least one normal fuse and at least one dummy fuse. The boot-up control circuit may include a fuse array controller configured to determine whether or not to start a normal boot-up operation for the at least one normal fuse according to a comparison result between expected data and test fuse data output from the at least on dummy fuse through a test boot-up operation.

In an embodiment of the present disclosure, a semiconductor apparatus may be provided. The semiconductor apparatus may include a fuse array including a plurality of normal fuses and a plurality of dummy fuses. The semiconductor apparatus may include a boot-up control circuit configured to generate a boot-up enable signal indicating whether or not to start a normal boot-up operation according to a comparison result between expected data and fuse data output from the plurality of dummy fuses through a test boot-up operation and to generate a fuse clock signal. The semiconductor apparatus may include a memory cell array configured to perform the normal boot-up operation which stores fuse data output from the plurality of normal fuses according to the fuse clock signal based on the boot-up enable signal being activated.

### BRIEF DESCRIPTION OF THE DRAWINGS

FIG. 1 is a diagram illustrating an example of a representation of a configuration of a semiconductor apparatus according to an embodiment of the present disclosure.

FIG. 2 is a diagram illustrating an example of a representation of an internal configuration of a fuse array controller of FIG. 1.

FIG. 3 is a diagram illustrating an example of a representation of an internal configuration of a boot-up determination circuit of FIG. 2.

FIG. 4 is a diagram illustrating an example of a representation of an internal configuration of an expected data generation unit of FIG. 3.

FIG. 5 is a diagram illustrating an example of a representation of an internal configuration of a boot-up ready signal generation unit of FIG. 3.

FIG. 6 is a diagram illustrating an example of a representation of an internal configuration of a comparison unit of FIG. 3.

FIG. 7 is a diagram illustrating an example of a representation of an internal configuration of an external control signal generation unit of FIG. 3.

FIG. 8 is a diagram illustrating an example of a representation of an internal configuration of a count reset pulse generation unit of FIG. 3.

FIGS. 9 and 10 are examples of timing diagrams for explaining a boot-up control operation according to an embodiment of the present disclosure.

FIG. 11 illustrates a block diagram of an example of a representation of a system employing a semiconductor apparatus and or boot-up control circuit with the various embodiments discussed above with relation to FIGS. 1-10.

### DETAILED DESCRIPTION

Various embodiments will be described with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present disclosure is described herein with reference to cross-section and/or plan illustrations of idealized embodiments of the present disclosure. However, embodiments of the present disclosure should not be construed as limiting. Although a few embodiments will be illustrated and described, it will be appreciated by those of ordinary skill in the art that changes may be made in these embodiments without departing from the principles and spirit of the present disclosure.

Various embodiments may be provided relating to a boot-up control circuit capable of improving reliability of a boot-up operation and a semiconductor apparatus including the same.

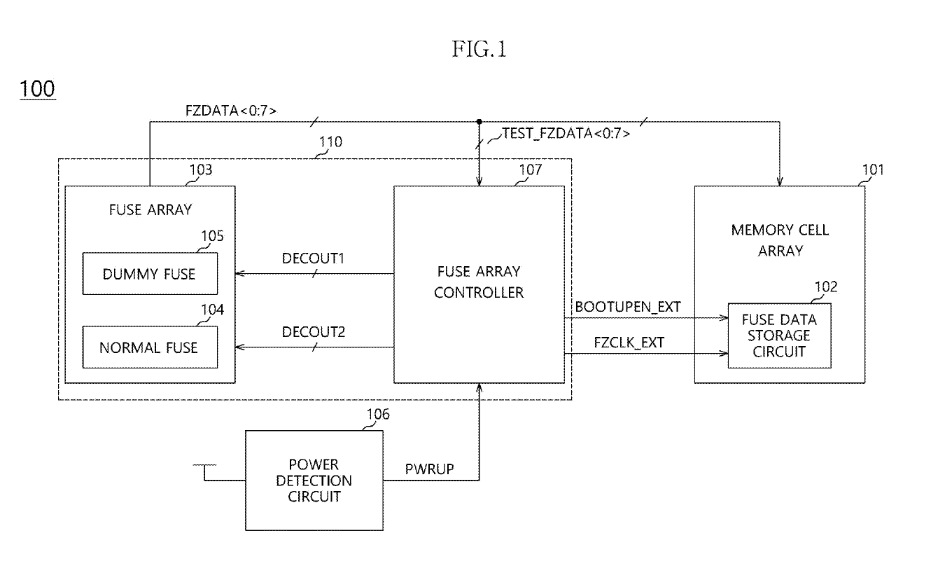

Referring to FIG. 1, a semiconductor apparatus 100 according to an embodiment may include a memory cell array 101, a fuse array 103, a power detection circuit 106, and a fuse array controller 107. The semiconductor apparatus 100 may include a boot-up control circuit 110. In an embodiment, the boot-up control circuit 110 may include the fuse array 103 and the fuse array controller 107.

The memory cell array 101 may include a plurality of memory cells (not illustrated) and a fuse data storage circuit 102.

The fuse data storage circuit 102 may store fuse data FZDATA<0:7> according to a fuse clock signal FZCLK_EXT when a boot-up enable signal BOOTUPEN_EXT is activated.

The stored fuse data FZDATA<0:7> may be used in an operation which repairs a defective address in an access operation to the memory cell array 101.

The fuse array 103 may include a plurality of normal fuses 104 and a plurality of dummy fuses 105.

The fuse array 103 may output information stored in the plurality of normal fuses 104 and the plurality of dummy fuses 105 as the fuse data FZDATA<0:7> according to a first decoding signal DECOUT1 and a second decoding signal DECOUT2.

The fuse array 103 may output the information stored in the plurality of dummy fuses 105 as the fuse data FZDATA<0:7> according to the first decoding signal DECOUT1.

The fuse array 103 may output the information stored in the plurality of normal fuses 104 as the fuse data FZDATA<0:7> according to the second decoding signal DECOUT2.

The defective address information of the memory cell array 101 may be stored in the plurality of normal fuses 104.

The plurality of dummy fuses 105 may be configured for a test boot-up operation performed prior to the normal boot-up operation and test data of which a value is previously known other the substantial defective address information may be stored in the plurality of dummy fuses 105.

The plurality of dummy fuses 105 may be divided in fuse set units, and test data having different combinations, for example, ‘10101010’, ‘01010101’, ‘00000000’, and ‘11111111’ may be stored in the fuse sets to increase test accuracy.

Other than partial fuses among fuses in the fuse array 103 used as the plurality of normal fuses 104, the remaining fuses may be assigned to the plurality of dummy fuses 105.

The fuses of the fuse array 103 may have the same configuration and may be fabricated through the same process, and thus the plurality of normal fuses 104 and the plurality of dummy fuses 105 may have the same operation characteristic.

Since the plurality of dummy fuses 105 have the same operation characteristic as the plurality of normal fuses 104, an operation state of the plurality of normal fuses 104 may be previously tested through a process of storing test data of which a value is previously known in the plurality of dummy fuses 105 through a fuse programming operation and then reading the fuse data FZDATA<0:7> stored in the plurality of dummy fuses 105 through a test boot-up operation.

Expected data EXPDATA<0:7> of FIG. 3 to be described later may have the same value as the test data. Accordingly, when the fuse data FZGATA<0:7> is identical with the expected data EXTDATA<0:7>, the plurality of dummy fuses 105 may be determined to be normally operated. Accordingly, the plurality of normal fuses 104 having the same operation characteristic as the plurality of dummy fuses 105 may also be determined to be normally operated.

Normal data related to the normal operation of the semiconductor apparatus may be stored in the plurality of memory cells of the memory cell array 101.

The power detection circuit 106 may generate a power up signal PWRUP indicating whether or not a power voltage such as VDD or VPP reaches a fixed level.

The fuse array controller 107 may generate the boot-up enable signal BOOTUPEX_EXT and the fuse clock signal FZCLK_EXT by determining whether or not to start the normal boot-up operation for the plurality of normal fuses 104 according to a comparison result between the test fuse data TEST_FZDATA<0:7> output from the plurality of dummy fuses 104 and the expected data EXPDATA<0:7> through the test boot-up operation.

For clarity, the fuse data FZDATA<0:7> which is output from the plurality of dummy fuses 105 and are provided to the fuse array controller 107 in the test boot-up operation may refer to the test fuse data TEST_FZDATA<0:7>.

The fuse array controller 107 may perform the test boot-up operation according to the power up signal PWRUP.

The fuse array controller 107 may generate a decoding signal DECOUT which allows corresponding test fuse data TEST_FZDATA<0:7> to be output by sequentially selecting the fuse data of the plurality of dummy fuses 105 in the test boot-up operation and sequentially selecting the plurality of normal fuses in the normal boot-up operation.

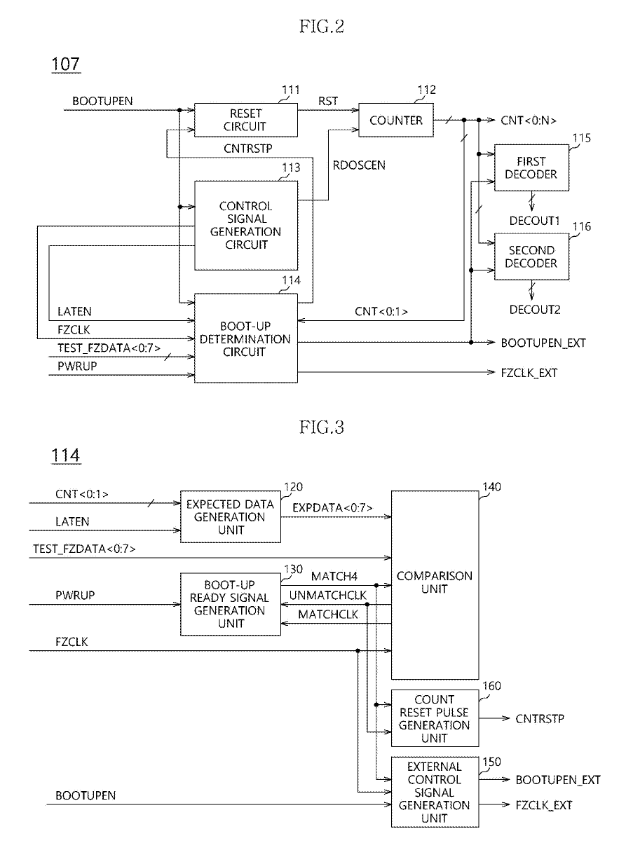

Referring to FIG. 2, the fuse array controller 107 may include a reset circuit 111, a counter 112, a control signal generation circuit 113, a boot-up determination circuit 114, a first decoder 115, and a second decoder 116.

The fuse array controller 107 may activate a preliminary boot-up enable signal BOOTUPEN after a fixed timing according to the power up signal PWRUP.

The reset circuit 111 may generate a reset signal RST according to the preliminary boot-up enable signal BOOTUPEN and a counter rest pulse CNTRSTP.

The reset circuit 111 may activate the reset signal RST when any one of the preliminary boot-up enable signal BOOTUPEN and the counter reset pulse CNTRSTP is activated.

The reset circuit 111 may comprise logic gates which output the reset signal RST by OR operation about the preliminary boot-up enable signal BOOTUPEN and the counter reset pulse CNTRSTP.

The counter 112 may vary (for example, sequentially increase) a value of the boot-up count signal CNT<0:N> according to an oscillation enable signal RDOSCEN.

The counter 112 may initialize the boot-up count signal CNT<0:N> according to the reset signal RST.

The control signal generation circuit 113 may generate the oscillation enable signal RDOSCEN, a latch enable signal LATEN, and a preliminary fuse clock signal FZCLK according to the preliminary boot-up enable signal BOOTUPEN.

The control signal generation circuit 113 may activate the oscillation enable signal RDOSCEN, the latch enable signal LATEN, and the preliminary fuse clock signal FZCLK when the preliminary boot-up enable signal BOOTUPEN is activated.

The control signal generation circuit 113 may comprise pulse generators that activate the oscillation enable signal RDOSCEN, the latch enable signal LATEN, and the preliminary fuse clock signal FZCLK at predetermined orders according to an activation of the preliminary boot-up enable signal BOOTUPEN.

The boot-up determination circuit 114 may generate the boot-up enable signal BOOTUPEN_EXT and the fuse clock signal FZCLK_EXT according to the latch enable signal LATEN, the preliminary fuse clock signal FZCLK, the test fuse data TEST_FZDATA<0:7>, the power up signal PWRUP, and a test count signal CNT<0:1>.

A portion of the boot-up count signal CNT<0:N> may be used as the test count signal CNT<0:1>.

The first decoder 115 may generate the first decoding signal DECOUT1 which allows the test fuse data TEST_FZDATA<0:7> to be output from the plurality of dummy fuses 105 by decoding the boot-up count signal CNT<0:N> in an inactivation period of the boot-up enable signal BOOTUPEN_EXT.

The second decoder 116 may generate the second decoding signal DECOUT2 which allows the test fuse data TEST_FZDATA<0:7> to be output from the plurality of normal fuses 104 by decoding the boot-up count signal CNT<0:N> in an activation period of the boot-up enable signal BOOTUPEN_EXT.

Referring to FIG. 3, the boot-up determination circuit 114 may include an expected data generation unit 120, a boot-up ready signal generation unit 130, a comparison unit 140, an external control signal generation unit 150, and a count reset pulse generation unit 160.

The expected data generation unit 120 may generate the expected data EXPDATA<0:7> according to the latch enable signal LATEN and the test count signal CNT<0:1>.

The boot-up ready signal generation unit 130 may generate a boot-up ready signal MATCH4 according to the power up signal PWRUP, a match clock signal MATCHCLK, and an unmatch clock signal UNMATCHCLK.

The comparison unit 140 may generate the match clock signal MATCHCLK and the unmatch clock signal UNMATCHCLK using the boot-up ready signal MATCH4 and the preliminary fuse clock signal FZCLK according to a comparison result between the test fuse data TEST_FZDATA<0:7> and the expected data EXPDATA<0:7>.

The comparison unit 140 may activate only the match clock signal MATCHCLK from the match clock signal MATCHCLK and the unmatch clock signal UNMATCHCLK when the test fuse data TEST_FZDATA<0:7> is identical with the expected data EXPDATA<0:7>.

The comparison unit 140 may activate only the unmatch clock signal UNMATCHCLK from the match clock signal MATCHCLK and the unmatch clock signal UNMATCHCLK even when any one bit of the test fuse data TEST_FZDATA<0:7> is not identical with the expected data EXPDATA<0:7>.

The external control signal generation unit 150 may generate the fuse clock signal FZCLK_EXT and the boot-up enable signal BOOTUPEN_EXT using the preliminary fuse clock signal FZCLK and the preliminary boot-up enable signal BOOTUPEN according to the boot-up ready signal MATCH4.

The external control signal generation unit 150 may output the preliminary fuse clock signal FZCLK and the preliminary boot-up enable signal BOOTUPEN as the fuse clock signal FZCLK_EXT and the boot-up enable signal BOOTUPEN_EXT when the boot-up ready signal MATCH4 is activated.

The external control signal generation unit 150 may maintain the fuse clock signal FZCLK_EXT and the boot-up enable signal BOOTUPEN_EXT to an inactivation level (for example, a low level) when the boot-up ready signal MATCH4 is inactivated. Further, the logic levels of the signals may be different from or the opposite of those described. For example, a signal described as having a logic “high” level may alternatively have a logic “low” level, and a signal described as having a logic “low” level may alternatively have a logic “high” level.

The count reset pulse generation unit 160 may generate the count reset pulse CNTRSTP according to the boot-up ready signal MATCH4 and the unmatch clock signal UNMATCHCLK.

The count reset pulse generation unit 160 may generate the count reset pulse CNTRSTP when any one of the boot-up ready signal MATCH4 and the unmatch clock signal UNMATCHCLK is activated.

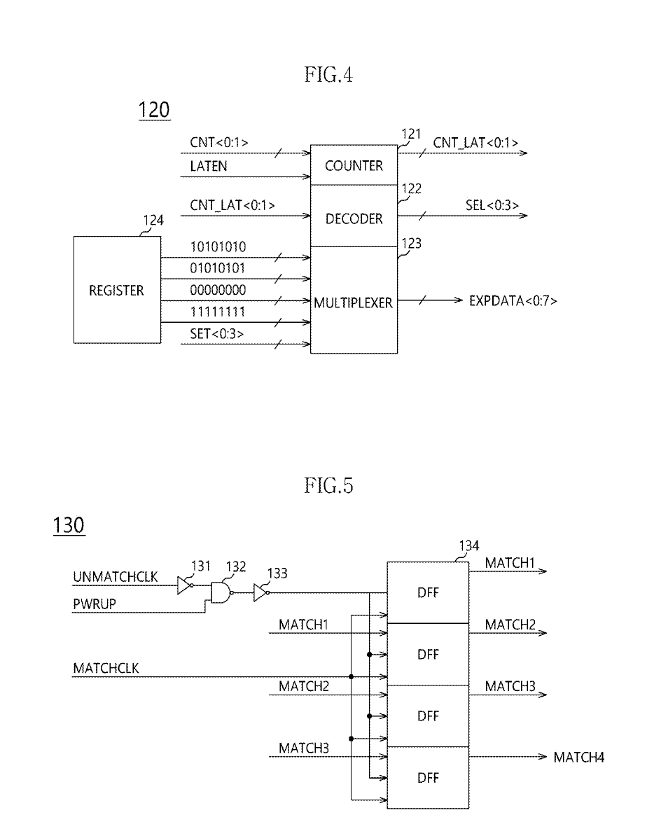

Referring to FIG. 4, the expected data generation unit 120 of FIG. 3 may include a counter 121, a decoder 122, a multiplexer 123, and a register 124.

The register 124 may store a plurality of pieces of data. The plurality of pieces of data stored in the register 124 may have the same value as the plurality of pieces of data stored in the plurality of dummy fuses as described in FIG. 1.

The plurality of pieces of data stored in the register 124 may have, for example but not limited to, a combination of ‘10101010’, ‘01010101’, and ‘00000000’, ‘11111111’.

The counter 121 may generate a preliminary selection signal CNT_LAT<0:1> by counting the test count signal CNT<0:1> according to the latch enable signal LATEN.

The decoder 122 may generate a selection signal SEL<0:3> by decoding the preliminary selection signal CNT_LAT<0:1>.

The multiplexer 123 may sequentially select the plurality of pieces of data ‘10101010’, ‘01010101’, ‘00000000’, and ‘11111111’ stored in the register 124 according to the selection signal SEL<0:3> and output the selected data as the expected data EXTDATA<0:7>.

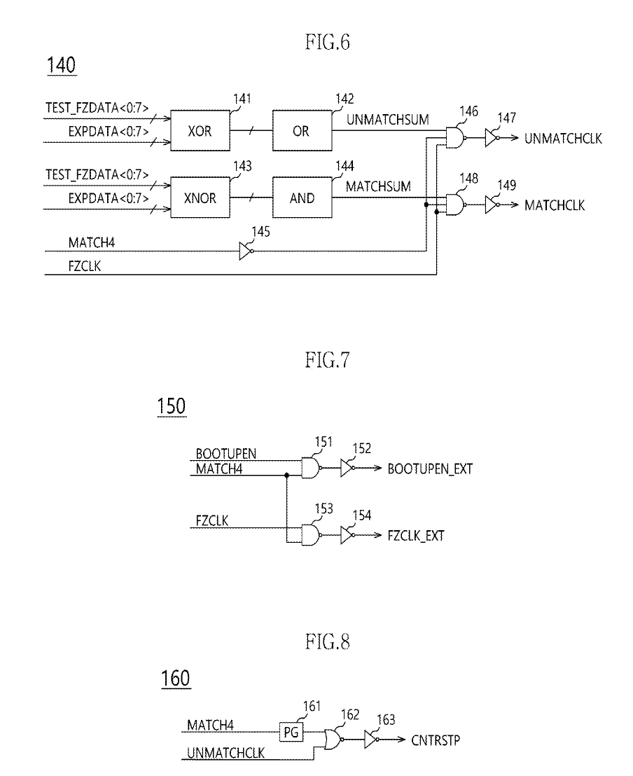

Referring to FIG. 5, the boot-up ready signal generation unit 130 may include first to third logic gates 131 to 133 and a plurality of flip flops 134.

The first logic gate 131 may invert the unmatch clock signal UNMATCHCLK and output an inverted unmatch clock signal.

The second and third logic gates 132 and 133 may perform a logic AND operation on an output of the first logic gate 131 and the power up signal PWRUP and output a logic AND operation result.

The plurality of flip flops 134 may generate a plurality of preliminary signals MATCH1 to MATCH4 by sequentially shifting an output of the third logic gate 133 according to the match clock signal MATCHCLK and output a final output of the plurality of preliminary signals MATCH1 to MATCH4 as the boot-up ready signal MATCH4.

For example, the boot-up ready signal generation unit 130 may activate the boot-up ready signal MATCH4 when the unmatch clock signal UNMATCHCLK is not generated while the match clock signal MATCHCLK is generated four times.

Referring to FIG. 6, the comparison unit 140 may include an XOR gate array 141, an OR gate array 142, an XNOR gate array 143, an AND gate array 144, and first to fifth logic gates 145 to 149.

The XOR gate array 141 may perform a logic XOR operation on the test fuse data TEST_FZDATA<0:7> and the expected data EXTDATA<0:7> and output a logic XOR operation result.

The OR gate array 142 may generate an unmatch sum signal UNMATCHSUM by performing a logic OR operation on an output of the XOR gate array 141.

The XNOR gate array 143 may perform a logic XNOR operation on the test fuse data TEST_FZDATA<0:7> and the expected data EXTDATA<0:7> and output a logic XNOR operation result.

The AND gate array 144 may generate a match sum signal MATCHSUM by performing a logic AND operation on an output of the XNOR gate array 143.

The first logic gate 145 may invert the boot-up ready signal MATCH4 and output the inverted boot-up ready signal.

The second and third logic gates 146 and 147 may perform an AND logic operation on the unmatch sum signal UNMATCHSUM, an output of the first logic gate 145, and the preliminary fuse clock signal FZCLK and output a logic AND operation result as the unmatch clock signal UNMATCHCLK.

The fourth and fifth logic gates 148 and 149 may perform an logic AND operation on the match sum signal MATCHSUM, the output of the first logic gate 145, and the preliminary fuse clock signal FZCLK and output a logic AND operation result as the match clock signal MATCHCLK.

The comparison unit 140 may output the preliminary fuse clock signal FZCLK as the match clock signal MATCHCLK when the test fuse data TEST_FZDATA<0:7> is identical with the expected data EXTDATA<0:7>.

The comparison unit 140 may output the preliminary fuse clock signal FZCLK as the unmatch clock signal UNMATCHCLK when any one bit of the test fuse data TEST_FZDATA<0:7> is not identical with the expected data EXTDATA<0:7>.

The comparison unit 140 may inactivate both the match clock signal MATCHCLK and the unmatch clock signal UNMATCHCLK when the boot-up ready signal MATCH4 is activated.

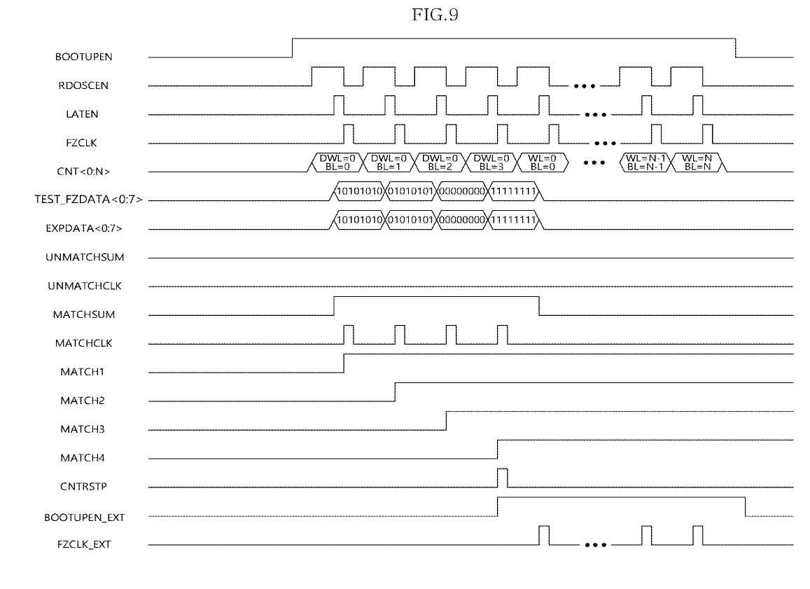

Referring to FIG. 7, the external control signal generation unit 150 may include first to fourth logic gates 151 to 154.

The first and second logic gates 151 and 152 may generate the boot-up enable signal BOOTUPEN_EXT by performing a logic AND operation on the preliminary boot-up enable signal BOOTUPEN and the boot-up ready signal MATCH4.

The third and fourth logic gates 153 and 154 may generate the fuse clock signal FZCLK_EXT by performing a logic AND operation on the preliminary fuse clock signal FZCLK and the boot-up ready signal MATCH4.

The external control signal generation unit 150 may output the preliminary boot-up enable signal BOOTUPEN as the boot-up enable signal BOOTUPEN_EXT and output the preliminary fuse clock signal FZCLK as the fuse clock signal FZCLK_EXT when the boot-up ready signal MATCH4 is activated.

Referring to FIG. 8, a count reset pulse generation unit 160 may include a pulse generator (PG) 161 and first and second logic gates 162 and 163.

The pulse generator 161 may generate a pulse signal according to the boot-up ready signal MATCH4.

The first and second logic gates 162 and 163 may generate the count reset pulse CNTRSTP by performing a logic OR operation on an output of the pulse generator 161 and the unmatch clock signal UNMATCHCLK.

A boot-up control operation of the semiconductor apparatus 100 according to an embodiment will be described based on the configurations of FIGS. 1 to 8 with reference to FIG. 9.

FIG. 9 illustrates an example of the boot-up control operation that the test fuse data TEST_FZDATA<0:7> is identical with the expected data EXTDATA<0:7>.

First, a fuse programming process which stores test data in fuse sets of the plurality of dummy fuses 105 of FIG. 1 may be preferentially performed.

The preliminary boot-up enable signal BOOTUPEN may be activated after a fixed timing according to the power up signal PWRUP and a test boot-up operation may be performed.

The oscillation enable signal RDOSCEN, the latch enable signal LATEN, and the preliminary fuse clock signal FZCLK may be generated during an activation period of the preliminary boot-up enable signal BOOTUPEN.

The boot-up count signal CNT<0:N> may be generated according to the oscillation enable signal RDOSCEN.

The fuse sets of the plurality of dummy fuses 105 of FIG. 1 may be sequentially selected according to the boot-up count signal CNT<0:N> and thus the test fuse data TEST_FZDATA<0:7> may be output.

For example, a portion of fuses coupled to one word line (for clarity, dummy word line: DWL=0) may be used as the plurality of dummy fuses 105. In an embodiment, for example, a remaining portion of fuses of the fuse array 103 other than a portion of the fuses of the fuse array 103 used as the plurality of normal fuses 104 are assigned to the plurality of dummy fuses 105.

Corresponding fuse sets may be sequentially selected by sequentially increasing a bit line BL such as 0, 1, 2, and 3 with respect to DWL=0 and thus the test fuse data TEST_FZDATA<0:7> may be output as ‘10101010’, ‘01010101’, ‘00000000’, and ‘11111111’.

At the same time, the plurality of pieces of data ‘10101010’, ‘01010101’, ‘00000000’, ‘11111111’ stored in the register 124 may be sequentially output as the expected data EXTDATA<0:7>.

The match sum signal MATCHSUM may be activated since the test fuse data TEST_FZDATA<0:7> is identical with the expected data EXPDATA<0:7> and the match clock signal MATCHCLK may be generated during an activation period of the match sum signal MATCHSUM.

The unmatch clock signal UNMATCHCLK and the unmatch sum signal UNMATCHSUM may be maintained in an inactivation state since the test fuse data TEST_FZDATA<0:7> is identical with the expected data EXPDATA<0:7>.

The preliminary signals MATCH1 to MATCH3 may be sequentially activated according to the match clock signal MATCHCLK and finally the boot-up ready signal MATCH4 may be activated.

The test boot-up operation may be completed as the boot-up ready signal MATCH4 is activated.

As the boot-up ready signal MATCH4 is activated, the boot-up enable signal BOOTUPEN_EXT may be activated and the fuse clock signal FZCLK_EXT may be generated during the activation period of the boot-up enable signal BOOTUPEN_EXT. Accordingly, the normal boot-up operation may start.

As the boot-up ready signal MATCH4 is activated, the count reset pulse CNTRSTP may be generated and the boot-up count signal CNT<0:N> may be initialized according to the count reset pulse CNTRSTP.

As the boot-up count signal CNT<0:N> is initialized and then the value of the boot-up count signal CNT<0:N> is increased again, the fuse sets of the plurality of normal fuses 104 of FIG. 1 may be sequentially selected and thus the fuse data FZDATA<0:7> may be output.

For example, the fuse sets of the plurality of normal fuses 104 may be sequentially selected by sequentially increasing the word line WL<0:N> and the bit line BL<0:N> according to the boot-up count signal CNT<0:N> and thus the fuse data FZDATA<0:7> may be output.

The fuse data storage circuit 102 of the memory cell array 101 of FIG. 1 may store the fuse data FZDATA<0:7> according to the fuse clock signal FZCLK_EXT during the activation period of the boot-up enable signal BOOTUPEN_EXT.

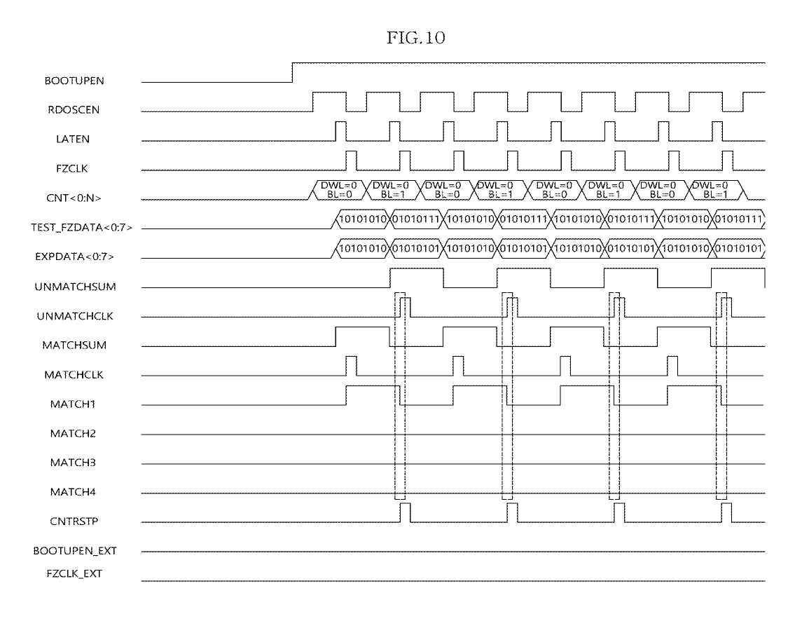

A boot-up control operation of the semiconductor apparatus 100 according to an embodiment will be described based on the configurations of FIGS. 1 to 8 with reference to FIG. 10.

FIG. 10 illustrates an example of the boot-up control operation that the test fuse data TEST_FZDATA<0:7> is not identical with the expected data EXTDATA<0:7>.

First, a fuse programming process which stores test data in fuse sets of the plurality of dummy fuses 105 of FIG. 1 may be preferentially performed.

The preliminary boot-up enable signal BOOTUPEN may be activated after a fixed timing according to the power up signal PWRUP and a test boot-up operation may be performed.

The oscillation enable signal RDOSCEN, the latch enable signal LATEN, and the preliminary fuse clock signal FZCLK may be generated during the activation period of the preliminary boot-up enable signal BOOTUPEN.

The boot-up count signal CNT<0:N> may be generated according to the oscillation enable signal RDOSCEN.

The fuse sets of the plurality of dummy fuses 105 of FIG. 1 may be sequentially selected according to the boot-up count signal CNT<0:N> and the test fuse data TEST_FZDATA<0:7> may be sequentially output. At the same time, the expected data EXTDATA may be sequentially output.

Since ‘10101010’ as the first test fuse data TEST_FZDATA<0:7> is identical with ‘10101010’ as the first expected data EXPDATA<0:7>, the match sum signal MATCHSUM may be activated and the match clock signal MATCHCLK may be generated during an activation period of the match sum signal MATCHSUM.

Since the second test fuse data TEST_FZDATA<0:7> is ‘01010111’ and the second expected data EXPDATA<0:7> is ‘01010101’, the second test fuse data TEST_FZDATA<0:7> is not identical with the second expected data EXPDATA<0:7>.

Since the second test fuse data TEST_FZDATA<0:7> is not identical with the second expected data EXPDATA<0:7>, the match sum signal MATCHSUM and the match clock signal MATCHCLK may be inactivated and the unmatch clock signal UNMATCHCLK may be generated during an activation period of the unmatch sum signal UNMATCHSUM.

Since the identification between the test fuse data TEST_FZDATA<0:7> and the expected data EXPDATA<0:7> is not repeated, only MATCH1 among the preliminary signals MATCH1 to MATCH3 may be activated and then may be inactivated again. Accordingly, the boot-up ready signal MATCH4 may be maintained in the inactivation state.

The count reset pulse CNTRSTP may be generated according to the unmatch clock signal UNMATCHCLK and the boot-up count signal CNT<0:N> may be initialized according to the count reset pulse CNTRSTP.

The operation that the dummy fuse 105 corresponding to the dummy word line DWL=0 and the bit line BL=0 is selected again to output the test fuse data TEST_FZDATA<0:7> may be repeatedly performed, and the operation may refer to the abnormal operation of the fuse array 103.

As described above, when the abnormal operation of the fuse array 103 is detected, the boot-up ready signal MATCH4 may be maintained in the inactivation state. Accordingly, the boot-up enable signal BOOTUPEN_EXT and the fuse clock signal FZCLK_EXT may be maintained in the inactivation state to interrupt start of the normal boot-up operation.

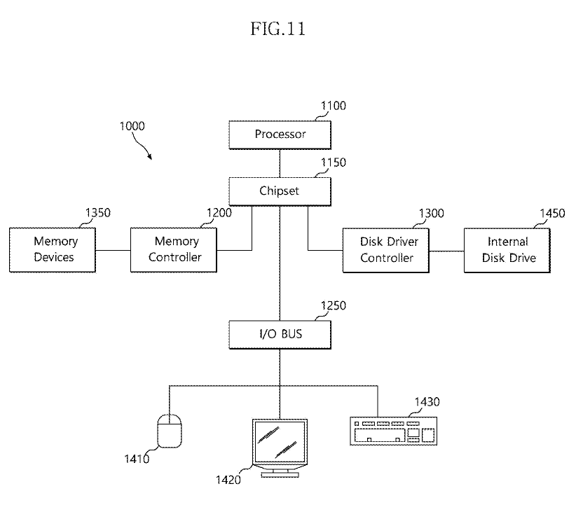

The semiconductor apparatuses and or boot-up control circuits as discussed above (see FIGS. 1-10) are particular useful in the design of other memory devices, processors, and computer systems. For example, referring to FIG. 11, a block diagram of a system employing a semiconductor apparatus and or boot-up control circuit in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor apparatus and or boot-up control circuit as discussed above with reference to FIGS. 1-10. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor apparatus and or boot-up control circuit as discussed above with relation to FIGS. 1-10, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 11 is merely one example of a semiconductor apparatus and or boot-up control circuit as discussed above with relation to FIGS. 1-10. In alternate embodiments, such as, for example but not limited to, cellular phones or digital cameras, the components may differ from the embodiments illustrated in FIG. 11.

The above described embodiments are intended to illustrate and not to limit the present disclosure. Various alternatives and equivalents are possible. The disclosure is not limited by the embodiments described herein. Nor is the disclosure limited to any specific type of semiconductor device. Other additions, subtractions, or modifications are obvious in view of the present disclosure and are intended to fall within the scope of the appended claims.

What is claimed is:

1. A boot-up control circuit comprising:
a fuse array including a plurality of normal fuses and a plurality of dummy fuses; and
a fuse array controller configured to determine whether or not to start a normal boot-up operation for the plurality of normal fuses according to a comparison result between expected data and test fuse data output from the plurality of dummy fuses through a test boot-up operation.

2. The boot-up control circuit of claim 1, wherein a remaining portion of fuses of the fuse array other than a portion of the fuses of the fuse array used as the plurality of normal fuses are assigned to the plurality of dummy fuses.

3. The boot-up control circuit of claim 1, wherein the fuse array controller includes:
a counter configured to vary a value of a boot-up count signal according to an oscillation enable signal;
a control signal generation circuit configured to generate the oscillation enable signal and a preliminary fuse clock signal according to a preliminary boot-up enable signal;
a boot-up determination circuit configured to generate a boot-up enable signal and a fuse clock signal according to the preliminary fuse clock signal, the test fuse data, and the boot-up count signal; and
a first decoder configured to allow the test fuse data to be output from the plurality of dummy fuses by decoding the boot-up count signal during an inactivation period of the boot-up enable signal.

4. The boot-up control circuit of claim 3, further comprising a reset circuit configured to initialize the value of the boot-up count signal according to a counter reset pulse and the preliminary boot-up enable signal.

5. The boot-up control circuit of claim 3, further comprising a second decoder configured to allow fuse data to be output from the plurality of normal fuses by decoding the boot-up count signal during an activation period of the boot-up enable signal.

6. The boot-up control circuit of claim 3, wherein the boot-up determination circuit includes:
an expected data generation unit configured to generate the expected data according to the boot-up count signal;
a boot-up ready signal generation unit configured to generate a boot-up ready signal according to a match clock signal and an unmatch clock signal; and
a comparison unit configured to generate the match clock signal and the unmatch clock signal using the preliminary fuse clock signal and the boot-up ready signal according to the comparison result between the test fuse data and the expected data.

7. The boot-up control circuit of claim 6, further comprising an external control signal generation unit configured to generate the fuse clock signal and the boot-up enable signal using the preliminary fuse clock signal and the preliminary boot-up enable signal according to the boot-up ready signal.

8. The boot-up control circuit of claim 6, further comprising a count reset pulse generation unit configured to generate a count reset pulse for initializing the value of the boot-up count signal according to the boot-up ready signal and the unmatch clock signal.

9. The boot-up control circuit of claim 6, wherein the expected data generation unit includes:
a register configured to store a plurality of pieces of data having the same value as a plurality of pieces of data stored in the plurality of dummy fuses;
a counter configured to generate a preliminary selection signal by counting a portion of the boot-up count signal;
a decoder configured to generate a selection signal by decoding the preliminary selection signal; and
a multiplexer configured to sequentially select the plurality of pieces of data stored in the register according to the selection signal and output the selected data as the expected data.

10. A semiconductor apparatus comprising:
a fuse array including a plurality of normal fuses and a plurality of dummy fuses;
a boot-up control circuit configured to generate a boot-up enable signal indicating whether or not to start a normal boot-up operation according to a comparison result between expected data and fuse data output from the plurality of dummy fuses through a test boot-up operation and to generate a fuse clock signal; and
a memory cell array configured to perform the normal boot-up operation which stores fuse data output from the plurality of normal fuses according to the fuse clock signal based on the boot-up enable signal being activated.

11. The semiconductor apparatus of claim 10, wherein a remaining portion of fuses of the fuse array other than a portion of the fuses of the fuse array used as the plurality of normal fuses are assigned to the plurality of dummy fuses.

12. The semiconductor apparatus of claim 10, wherein the boot-up control circuit is configured to perform the test boot-up operation by generating a preliminary boot-up enable signal and a preliminary fuse clock signal based on a power up signal being activated.

13. The semiconductor apparatus of claim 10, wherein the boot-up control circuit includes:
a counter configured to vary a value of a boot-up count signal according to an oscillation enable signal;
a control signal generation circuit configured to generate the oscillation enable signal and a preliminary fuse clock signal according to a preliminary boot-up enable signal;
a boot-up determination circuit configured to generate the boot-up enable signal and the fuse clock signal according to the preliminary fuse clock signal, the fuse data, and the boot-up count signal;
a first decoder configured to allow the fuse data to be output from the plurality of dummy fuses by decoding the boot-up count signal during an inactivation period of the boot-up enable signal; and
a second decoder configured to allow the fuse data to be output from the plurality of normal fuses by decoding the boot-up count signal during an activation period of the boot-up enable signal.

14. The semiconductor apparatus of claim 13, further comprising a reset circuit configured to initialize the value of the boot-up count signal according to a counter reset pulse and the preliminary boot-up enable signal.

15. The semiconductor apparatus of claim 13, wherein the boot-up determination circuit includes:
an expected data generation unit configured to generate the expected data according to the boot-up count signal;
a boot-up ready signal generation unit configured to the generate a boot-up ready signal according to a match clock signal and an unmatch clock signal; and
a comparison unit configured to generate the match clock signal and the unmatch clock signal using the preliminary fuse clock signal and the boot-up ready signal according to the comparison result between the test fuse data and the expected data.

16. The semiconductor apparatus of claim 15, further comprising an external control signal generation unit configured to generate the fuse clock signal and the boot-up enable signal using the preliminary fuse clock signal and the preliminary boot-up enable signal according to the boot-up ready signal.

17. The semiconductor apparatus of claim 15, further comprising a count reset pulse generation unit configured to generate a count reset pulse for initializing the value of the boot-up count signal according to the boot-up ready signal and the unmatch clock signal.

18. The semiconductor apparatus of claim 15, wherein the expected data generation unit includes:
a register configured to store a plurality of pieces of data having the same value as a plurality of pieces of data stored in the plurality of dummy fuses;
a counter configured to generate a preliminary selection signal by counting a portion of the boot-up count signal;
a decoder configured to generate a selection signal by decoding the preliminary selection signal; and
a multiplexer configured to sequentially select the plurality of pieces of data stored in the register according to the selection signal and output the selected data as the expected data.

19. The semiconductor apparatus of claim 10, wherein the memory cell array includes:
a plurality of memory cells in which normal data related to a normal operation of the semiconductor memory is stored; and
a fuse data storage circuit configured to store the fuse data according to the fuse clock signal.
